(19) United States
(12) Patent Application Publication
(10) Pub. No.: US 2025/0227923 A1
(43) Pub. Date: Jul. 10, 2025

(54) SEMICONDUCTOR STRUCTURE AND FORMATION METHOD THEREOF

(71) Applicant: Winbond Electronics Corp., Taichung City (TW)

(72) Inventor: Hao-Chuan CHANG, Taichung City (TW)

(21) Appl. No.: 18/670,061

(22) Filed: May 21, 2024

(30) Foreign Application Priority Data
Jan. 9, 2024 (TW) 113100897

(51) Int. Cl. H10B 12/00

(52) U.S. Cl. CPC H10B 12/50; H10B 12/09

(57) ABSTRACT

A semiconductor structure and a formation method thereof are provided. The semiconductor structure includes a substrate, a conductive structure, a dielectric layer, a supporting layer, a first conductive layer, and a second conductive layer. The substrate includes an active area, a peripheral area, and a dummy area between the active area and the peripheral area. The conductive structure is disposed in the substrate. The dielectric layer is disposed on the substrate. The supporting layer is disposed on the dielectric layer. The thickness of the supporting layer in the peripheral area is smaller than the thickness of the supporting layer in the dummy area. The first conductive layer is disposed in the dummy area and is in contact with the supporting layer. The second conductive layer is disposed in the active area, extends through the dielectric layer, and is in contact with the conductive structure.

### CROSS REFERENCE TO RELATED APPLICATIONS

This Application claims priority of Taiwan Patent Application No. 113100897, filed on Jan. 9, 2024, the entirety of which is incorporated by reference herein.

### TECHNICAL FIELD

Some embodiments of the present disclosure relate to a semiconductor structure and a formation method thereof, and, in particular, to a semiconductor structure that can be used as a memory device after further processing, and a formation method thereof.

### BACKGROUND

With the trend of miniaturization of semiconductor devices, the size of memory devices is also continuously being reduced, in order to increase integration and improve performance. However, these continued size reductions have created issues with leakage current between adjacent elements, which can adversely affect memory performance.

Although existing semiconductor structures and the formation methods are gradually meeting their intended uses, they still do not meet the requirements in all respects. Therefore, there are still some problems to be overcome in the semiconductor structure and its formation method that can be used as a memory device after further processing.

### SUMMARY

A semiconductor structure of this invention is provided. The semiconductor structure includes a substrate, a conductive structure, a dielectric layer, a supporting layer, a first conductive layer, and a second conductive layer. The substrate includes an active area, a peripheral area, and a dummy area between the active area and the peripheral area. The conductive structure is disposed in the substrate. The dielectric layer is disposed on the substrate. The supporting layer is disposed on the dielectric layer, wherein the thickness of the supporting layer in the peripheral area is smaller than the thickness of the supporting layer in the dummy area. The first conductive layer is disposed in the dummy area and is in contact with the supporting layer. The second conductive layer is disposed in the active area, extends through the dielectric layer, and is in contact with the conductive structure.

A method of forming a semiconductor structure of this invention is provided. The forming method includes providing a substrate, wherein the substrate includes an active area, a peripheral area, and a dummy area between the active area and the peripheral area. The conductive structure is formed in the substrate. The dielectric layer is formed on the substrate. The supporting layer is formed on the dielectric layer. The supporting layer is patterned such that the thickness of the supporting layer in the peripheral area is smaller than the thickness of the supporting layer in the dummy area. The first conductive layer is formed, such that the first conductive layer is in contact with the supporting layer. The second conductive layer is formed, such that the second conductive layer is in contact with the conductive structure.

### BRIEF DESCRIPTION OF THE DRAWINGS

FIGS. 1 to 6 are schematic cross-sectional views illustrating formation of a semiconductor structure at various stages according to some embodiments of the present disclosure.

FIG. 7 is a schematic cross-sectional view of a semiconductor structure according to some embodiments of the present disclosure.

### DETAILED DESCRIPTION

Referring to FIG. 1, a substrate 100 is provided. The substrate 100 may include an active area AA, a peripheral area PA adjacent to the active area AA, and a dummy area DA between the active area AA and the peripheral area PA. The active area AA and the dummy area DA may be used as an array area, and the array area is adjacent to the peripheral area PA.

The substrate 100 may be a wafer such as silicon wafer, a semiconductor on insulator (SOI) substrate, or a bulk semiconductor substrate, a multi-layer substrate or a gradient substrate. The substrate 100 may be an element semiconductor, including silicon and germanium; a compound semiconductor, including: silicon carbide, gallium arsenide, gallium phosphide, indium phosphide, indium arsenide, and/or indium antimonide; or an alloy semiconductor, including: SiGe, GaAsP, AlInAs, AlGaAs, GaInAs, GaInP, and/or GaInAsP or a combination thereof. The substrate 100 may be a doped or undoped semiconductor substrate.

A conductive structure 110 is formed in the substrate 100. The conductive structure 110 may be disposed in the active area AA, the dummy area DA, and the peripheral area PA. The top surface of the conductive structure 110 may be lower than the top surface of the substrate 100. The conductive structure 110 may be a landing pad (contacting pad). For example, the landing pad may be disposed between the capacitor contact (not shown) and the contact plug (not shown), and the landing pad may electrically connect the capacitor contact and the contact plug. The conductive structure 110 may include conductive material. For example, the conductive material may include polycrystalline silicon; amorphous silicon; metals such as tungsten, copper, silver, gold, cobalt; metal nitrides such as tungsten nitride, titanium nitride; conductive metal oxides; other suitable materials; or a combination thereof, but the present disclosure is not limited thereto. In some embodiments, the conductive structure 110 may include tungsten.

A dielectric layer 200 is formed on the substrate 100. The dielectric layer 200 may be continuously disposed in the active area AA, the dummy area DA, and the peripheral area PA. In other words, the dielectric layer 200 may extend in the active area AA, the dummy area DA, and the peripheral area PA. The dielectric layer 200 may include an oxide such as silicon oxide, a nitride such as silicon nitride, an oxynitride such as silicon oxynitride, other suitable dielectric materials, or a combination thereof, but the present disclosure is not limited thereto. The dielectric layer 200 may be silicon oxide.

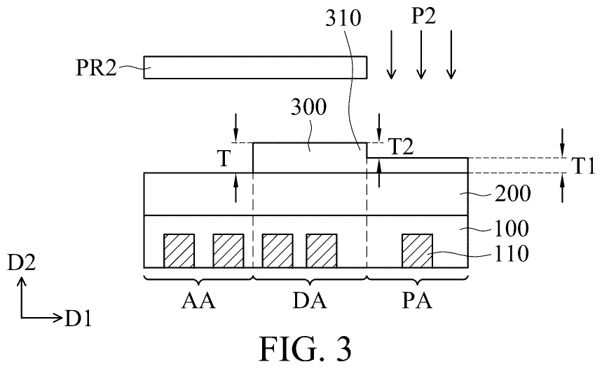

A supporting layer 300 is formed on the dielectric layer 200. The material and formation method of the supporting layer 300 may be the same as or different from the material and formation method of the dielectric layer 200. The supporting layer 300 may have a thickness T as shown in FIG. 3. As shown in FIG. 1, the supporting layer 300 may be continuously disposed in the active area AA, the dummy area DA, and the peripheral area PA. The supporting layer 300 and the dielectric layer 200 may include materials with different etching rates. The supporting layer 300 may include silicon nitride.

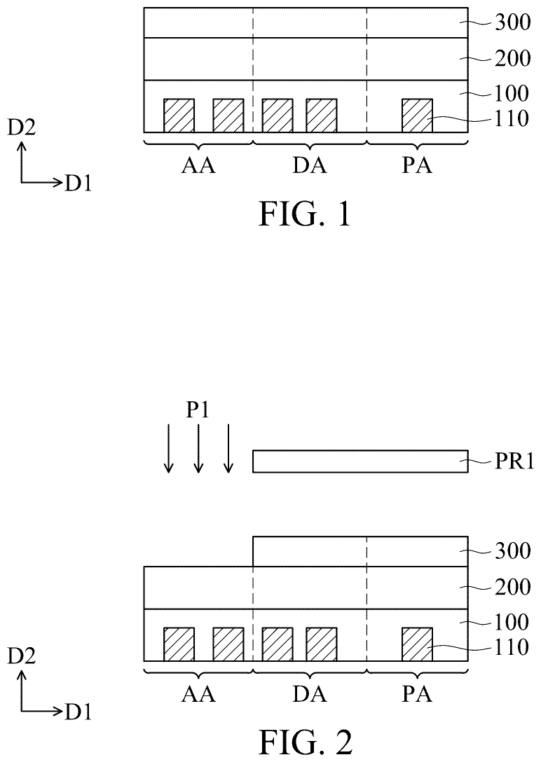

Referring to FIG. 2, the supporting layer 300 may be patterned, so as to adjust the thickness of the supporting layer 300 in different areas. A first mask PR1 is formed on the supporting layer 300. The first mask PR1 may cover the supporting layer 300 located in the dummy area DA and the peripheral area PA, and may expose the supporting layer 300 located in the active area AA. Next, by using the dielectric layer 200 as an etch stop layer, a first etching process P1 is performed to remove the supporting layer 300 located in the active area AA. Accordingly, based on the etching selectivity of the dielectric layer 200 and the supporting layer 300, such as the etching selectivity of silicon oxide and silicon nitride, the accuracy of executing the first etching process P1 is improved, thereby improving the reliability of the semiconductor structure. The first mask PR1 may be a photomask. The first etching process P1 may be dry etching, wet etching, or other suitable etching processes.

After performing the first etching process P1, the supporting layer 300 located in the dummy area DA and the peripheral area PA remains, and the supporting layer 300 located in the active area AA is removed. Then, the first mask PR1 is further removed by an ashing process. After performing the first etching process P1, the dielectric layer 200 located in the active area AA substantially remains. Therefore, when the subsequently formed dielectric stack is formed on the dielectric layer 200, the flatness of the top surface of the dielectric stack may be improved, thereby improving the reliability of the semiconductor structure. In some embodiments, a portion of dielectric layer 200 located in active area AA may be removed.

Referring to FIG. 3, the supporting layer 300 located in the peripheral area PA is thinned. A second mask PR2 is formed on the supporting layer 300. The second mask PR2 may cover the dielectric layer 200 located in the active area AA and the supporting layer 300 located in the dummy area DA, and the second mask PR2 may expose the supporting layer 300 located in the peripheral area PA. Next, a second etching process P2 is performed to remove a portion of the supporting layer 300 located in the peripheral area PA, and remain the remaining portion of the supporting layer 300 located in the peripheral area PA. After performing the second etching process P2, the supporting layer 300 may substantially cover the top surface of the dielectric layer 200 in the peripheral area PA. Accordingly, the supporting layer 300 may extend in the dummy area DA and the peripheral area PA to provide support (supporting force) for the subsequently formed first conductive layer. In some embodiments, the material of the second mask PR2 may be the same as or different from the material of the first mask PR1, and the second etching process P2 may be the same as or different from the first etching process P1.

After performing the second etching process P2, in the second direction D2, the thickness T1 of the supporting layer 300 in the peripheral area PA may be smaller than the thickness T of the supporting layer 300 in the dummy area DA. Since a thicker supporting layer 300 is provided in the peripheral area PA, the supporting layer 300 may provide support for the subsequently formed first conductive layer, thereby reducing the possibility of bending of the first conductive layer. Therefore, the leakage current caused by contacting the first conductive layer with other adjacent elements may be reduced. Since a thinner supporting layer 300 is provided in the dummy area DA, the obstruction of the supporting layer 300 to elements located below the supporting layer 300 during the subsequent annealing process may be reduced, thereby improving the repair effect of the subsequent annealing process.

The thickness T1 may account for 10% to 50% of the thickness T. For example, the ratio of the thickness T1 to the thickness T (the thickness T1/the thickness T) may be 10%, 15%, 20%, 25%, 30%, 35%, 40%, 45%, 50%, or any value or any range of values between the aforementioned values. For example, the ratio of the thickness T1 to the thickness T may be 3:10. If the thickness T1 is too large, the supporting layer 300 located in the peripheral area PA will block the subsequent annealing process, thereby reducing the repair effect of the annealing process. In detail, too thick the supporting layer 300 located in the peripheral area PA may cause the supporting layer 300 to excessively absorb or block the energy provided by the annealing process, thereby being unfavorable for performing the annealing process on elements located below the supporting layer 300. If the thickness T is too small, the support provided by the supporting layer 300 located in the dummy area DA will be reduced, causing the subsequently formed first conductive layer to bend and contact each other to cause a short circuit.

The supporting layer 300 may have a stepped portion 310. The stepped portion 310 of the supporting layer 300 is located at the boundary of the dummy area DA and the peripheral area PA. In the second direction D2, the stepped portion 310 may have a thickness T2. The ratio of the thickness T2 of the stepped portion 310 to the thickness T1 of the supporting layer 300 located in the peripheral area PA (the thickness T2/the thickness T1) is 1 to 5. For example, the ratio of the thickness T2 to the thickness T1 may be 1, 2, 2.3, 3, 4, 5, or any value or any range of values between the aforementioned values. For example, the ratio of the thickness T2 to the thickness T1 may be 7:3.

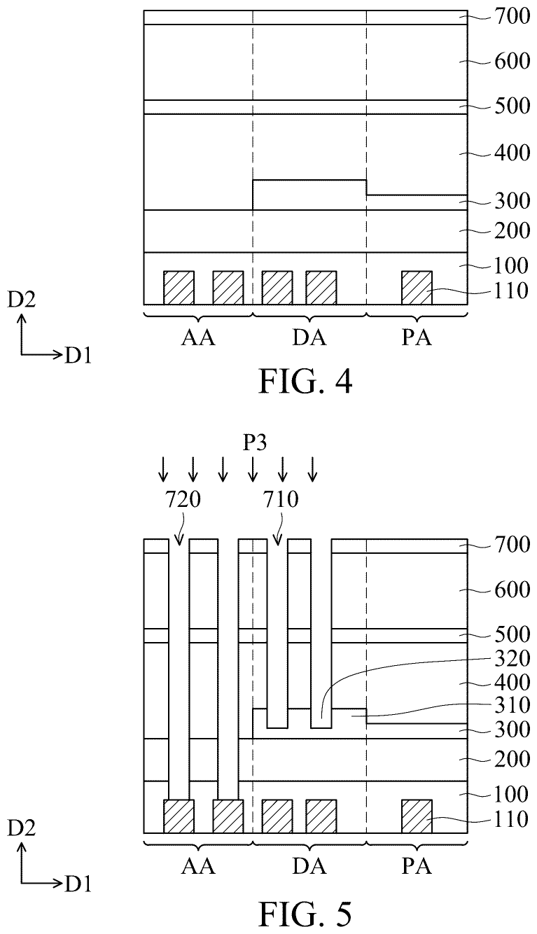

Referring to FIG. 4, a dielectric stack is formed on the dielectric layer 200 and the supporting layer 300, and the dielectric stack is in contact with the dielectric layer 200 located in the active area AA and the supporting layer 300 in the dummy area DA and the peripheral area PA. The dielectric stack may include a plurality of stacked dielectric layers. Each of the plurality of dielectric layers may respectively include an oxide such as silicon oxide, a nitride such as silicon nitride, an oxynitride such as silicon oxynitride, other suitable dielectric materials, or a combination thereof, but the present disclosure is not limited thereto. The material and formation method of the dielectric stack may be the same as or different from the material and formation method of the dielectric layer 200.

The dielectric stack may include alternately stacked oxide and nitride layers. The dielectric stack may include an oxide layer 400, a nitride layer 500, an oxide layer 600, and a nitride layer 700 stacked in sequence. The oxide layers 400, 600 may include oxides such as silicon oxide, and the nitride layers 500, 700 may include nitrides such as silicon nitride. The oxide layer 400 may contact the top surface of the dielectric layer 200 in the active area AA and the top surface of the supporting layer 300 in the dummy area DA and the peripheral area PA. Next, the nitride layer 500 may be formed on the oxide layer 400, the oxide layer 600 may be formed on the nitride layer 500, and the nitride layer 700 may be formed on the oxide layer 600.

Referring to FIG. 5, the dielectric stack is etched by a third etching process P3 to form the first opening 710 and the second opening 720. The first opening 710 and the second opening 720 may be formed in the same process. Due to the edge size effect and/or the etching load effect, the depths of the first opening 710 and the second opening 720 may be different in the second direction D2. For example, since the first opening 710 will be blocked by the supporting layer 300 during the formation of the first opening 710, the depth of the first opening 710 may be smaller than the depth of the second opening 720 in the second direction D2. The first opening 710 and the second opening 720 may be used to accommodate a capacitor, so that the first opening 710 and the second opening 720 may serve as capacitor trenches.

It should be noted that, in the present disclosure, the supporting layer 300 is disposed in the dummy area DA, and the supporting layer 300 is located between the dielectric stack and the dielectric layer 200, so that the supporting layer 300 may serve as a protective layer for elements below the supporting layer 300 (such as the dielectric layer 200 and the conductive structure 110). Therefore, when the third etching process P3 is performed, the supporting layer 300 may prevent the dielectric layer 200 and the conductive structure 110 from damaging by the first opening 710, thereby improving the reliability of the semiconductor structure.

The first opening 710 may expose the supporting layer 300 located in the dummy area DA. The dielectric stack and a portion of the supporting layer 300 are removed to form the first opening 710. The stepped portion 310 of the supporting layer 300 may have a recess 320, and a subsequently formed first conductive layer may be disposed in the recess 320. The bottom surface of the first opening 710 may be between the top surface of the supporting layer 300 and the bottom surface of the supporting layer 300. The first opening 710 may penetrate the dielectric stack, and the first opening 710 may be spaced apart from the dielectric layer 200 in the second direction D2. That is, the bottom surface of the recess 320 is higher than the top surface of the dielectric layer 200. Since the supporting layer 300 has a thicker thickness in the dummy area DA, the supporting layer 300 may improve the process flexibility (process window/process margin) of performing the third etching process P3. Since the supporting layer 300 has a thicker thickness in the dummy area DA, the bottom surface of the first opening 710 may be easily controlled to stay between the top surface and the bottom surface of the supporting layer 300. Therefore, the process flexibility of performing the third etching process P3 may be improved. In other embodiments, even though the first opening 710 may penetrate the dielectric stack and the supporting layer 300, the bottom surface of the first opening 710 may be between the top surface of the supporting layer 300 and the bottom surface of the supporting layer 300, so that the first opening 710 and the conductive structure 110 may be separated by a distance. That is, the bottom surface of the recess 320 is between the top surface and the bottom surface of the supporting layer 300. Accordingly, the bottom surface of the recess 320 and the conductive structure 110 is separated by a distance.

The second opening 720 may expose the top surface of the conductive structure 110 located in the active area AA. The dielectric stack, dielectric layer 200, and a portion of the substrate 100 are removed to form the second opening 720. The bottom surface of the second opening 720 is aligned with the top surface of the conductive structure 110.

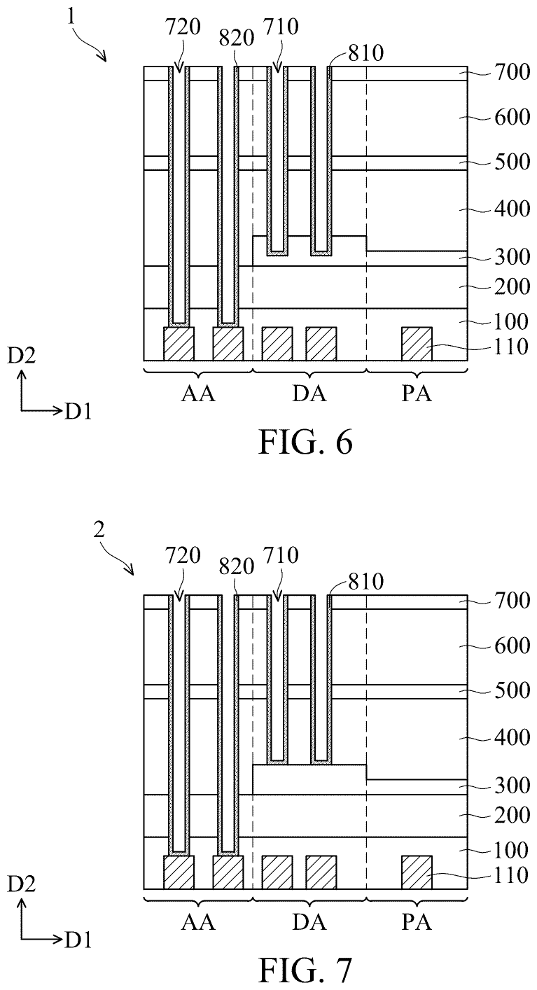

Referring to FIG. 6, a first conductive layer 810 is formed in the first opening 710, and a second conductive layer 820 is formed in the second opening 720, so that a semiconductor structure 1 of the present disclosure is obtained. The first conductive layer 810 is conformally formed in the first opening 710. The second conductive layer 820 is conformally formed in the second opening 720. The first conductive layer 810 and the second conductive layer 820 may be formed in the same process or in different processes. Further processes such as a planarization process are further performed. The first conductive layer 810 and/or the second conductive layer 820 may include conductive materials. For example, the conductive material may include polycrystalline silicon; amorphous silicon; metals such as tungsten, copper, silver, gold, cobalt; metal nitrides such as tungsten nitride, titanium nitride; conductive metal oxides; other suitable materials; or a combination thereof. The first conductive layer 810 and the second conductive layer 820 may include titanium nitride.

The first conductive layer 810 may be disposed in the dummy area DA, and the first conductive layer 810 may penetrate the dielectric stack and be in contact with the supporting layer 300 located in the dummy area DA. The first conductive layer 810 may be in contact with the recess 320 of the supporting layer 300, so that the first conductive layer 810 may be inserted into the supporting layer 300, thereby improving the reliability of forming the first conductive layer 810. The supporting layer 300 covers a portion of the sidewall of the first conductive layer 810. The bottom surface of the first conductive layer 810 may be lower than the top surface of the supporting layer 300, and the bottom surface of the first conductive layer 810 may be higher than the bottom surface of the supporting layer 300. Therefore, the supporting layer 300 may improve the stability of the first conductive layer 810.

For example, when the first conductive layer 810 includes titanium nitride, the first conductive layer 810 is easy to bend or tilt when forming the first conductive layer 810 due to the high material stress of titanium nitride. At the result, the first conductive layer 810 may be in contact with adjacent first conductive layer 810 or other elements thereby causing short circuit. However, since the supporting layer 300 may be in contact with the lower portion of the first conductive layer 810, the supporting layer 300 may improve the stability of the first conductive layer 810.

The second conductive layer 820 may be disposed in the active area AA, and the second conductive layer 820 may penetrate the dielectric stack and the dielectric layer 200 to contact the conductive structure 110 located in the active area AA. The second conductive layer 820 may be electrically connected to the conductive structure 110 in the active area AA. The second conductive layer 820 may be inserted into the substrate 100, thereby improving the reliability of forming the second conductive layer 820. For example, when the second conductive layer 820 includes titanium nitride with high material stress, the stability of the second conductive layer 820 may be improved by bringing the substrate 100 in contact with the lower portion of the second conductive layer 820.

Further processes may be performed on the semiconductor structure 1 to form a memory structure. The first conductive layer 810 and the second conductive layer 820 may serve as the lower electrode of the capacitor in the memory structure. Therefore, other dielectric layers may be further formed as the dielectric of the capacitor, and other conductive layers may be formed as the upper electrode of the capacitor. For example, the first conductive layer 810 and the second conductive layer 820 may serve as trench-shaped lower electrodes. Furthermore, in order to form the capacitor, the dielectric stack and the dielectric layer 200 located in the active area AA and the dummy area DA are further removed. Therefore, the supporting layer 300 and the dielectric layer 200 located in the peripheral area PA provide support for the first conductive layer 810, and the substrate 100 provides support for the second conductive layer 820.

Referring to FIG. 7, a semiconductor structure 2 of the present disclosure is shown. In the semiconductor structure 2, the aforementioned third etching process P3 for forming the first opening 710 may not remove the supporting layer 300, so that the top surface of the supporting layer 300 maintains a flat surface. In other words, the first opening 710 may penetrate the dielectric stack and the supporting layer 300 remains. Next, the first conductive layer 810 and the second conductive layer 820 are formed. The bottom surface of the first conductive layer 810 may be aligned with the top surface of the supporting layer 300. In other words, the third etching process P3 is performed, so that the first opening 710 at least contacts the top surface of the supporting layer 300. Accordingly, the bottom surface of the first conductive layer 810 may be at least aligned with or lower than the top surface of the supporting layer 300. Therefore, once at least a portion of the first conductive layer 810 may be in contact with the supporting layer 300, the supporting layer 300 may provide support for the first conductive layer 810. Thus, the problem of short circuit caused by the first conductive layer 810 being in contact with other elements may be avoided.

Accordingly, since the semiconductor structure of the present disclosure includes supporting layers with different thicknesses in the peripheral area and the dummy area, the reliability and process flexibility of the semiconductor structure may be improved. For example, disposing a thicker supporting layer in the dummy area may improve the support for the first conductive layer in the dummy area, and disposing a thinner supporting layer in the peripheral area may reduce or avoid the obstruction of the annealing process for the peripheral area.

The foregoing outlines features of several embodiments of the present disclosure, so that a person of ordinary skill in the art may better understand the aspects of the present disclosure. A person of ordinary skill in the art should appreciate that the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate comprising an active area, a peripheral area, and a dummy area between the active area and the peripheral area;
a conductive structure disposed in the substrate;
a dielectric layer disposed on the substrate;
a supporting layer disposed on the dielectric layer, wherein a thickness of the supporting layer in the peripheral area is smaller than the thickness of the supporting layer in the dummy area;
a first conductive layer disposed in the dummy area and being in contact with the supporting layer; and
a second conductive layer disposed in the active area, extending through the dielectric layer, and being in contact with the conductive structure.

2. The semiconductor structure according to claim 1, wherein the thickness of the supporting layer in the peripheral area accounts for 10% to 50% of the thickness of the supporting layer in the dummy area.

3. The semiconductor structure according to claim 1, wherein a bottom surface of the first conductive layer is lower than or aligned with a top surface of the supporting layer.

4. The semiconductor structure according to claim 3, wherein the bottom surface of the first conductive layer is higher than a bottom surface of the supporting layer.

5. The semiconductor structure according to claim 1, further comprising:
a dielectric stack disposed on the dielectric layer and the supporting layer and being in contact with the dielectric layer and the supporting layer.

6. The semiconductor structure according to claim 1, wherein the supporting layer and the dielectric layer comprise materials with different etching rates.

7. The semiconductor structure according to claim 1, wherein the supporting layer comprises silicon nitride, and the dielectric layer comprises silicon oxide.

8. The semiconductor structure according to claim 1, wherein the supporting layer has a stepped portion at a boundary of the dummy area and the peripheral area.

9. The semiconductor structure according to claim 8, wherein the stepped portion of the supporting layer has a recess, and the first conductive layer is disposed in the recess.

10. The semiconductor structure according to claim 9, wherein a bottom surface of the recess and the conductive structure is separated by a distance.

11. The semiconductor structure according to claim 9, wherein a bottom surface of the recess is higher than a top surface of the dielectric layer.

12. The semiconductor structure according to claim 9, wherein a bottom surface of the recess is between a top surface and a bottom surface of the supporting layer.

13. The semiconductor structure according to claim 1, wherein the supporting layer covers a portion of a sidewall of the first conductive layer.

14. A method of forming a semiconductor structure, comprising:
providing a substrate, wherein the substrate comprises an active area, a peripheral area, and a dummy area between the active area and the peripheral area;
forming a conductive structure in the substrate;
forming a dielectric layer on the substrate;
forming a supporting layer on the dielectric layer;
patterning the supporting layer, such that a thickness of the supporting layer in the peripheral area is smaller than a thickness of the supporting layer in the dummy area;
forming a first conductive layer, such that the first conductive layer is in contact with the supporting layer; and
forming a second conductive layer, such that the second conductive layer is in contact with the conductive structure.

15. The method according to claim 14, wherein patterning the supporting layer further comprises:
forming a first mask on the supporting layer, wherein the first mask exposes the supporting layer in the active area;
removing the supporting layer in the active area;
forming a second mask on the supporting layer, wherein the second mask exposes the supporting layer in the peripheral area; and
removing the supporting layer in the perimeter area.

16. The method according to claim 15, wherein the supporting layer in the active area is removed by using the dielectric layer as an etch stop layer.

17. The method according to claim 15, wherein a portion of the supporting layer in the peripheral area is removed, such that a remaining portion of the supporting layer in the peripheral area remains.

18. The method according to claim 15, wherein after the removal of the supporting layer in the peripheral area, the supporting layer covers the dielectric layer in the peripheral area.

19. The method according to claim 14, further comprising:
forming a dielectric stack on the dielectric layer and the supporting layer; and
etching the dielectric stack to form a first opening and a second opening, wherein the first opening exposes the supporting layer in the dummy area and the second opening exposes the conductive structure in the active area,
wherein the first conductive layer is formed in the first opening, and the second conductive layer is formed in the second opening.

20. The method according to claim 19, wherein the first opening is formed by etching the dielectric stack and the supporting layer, such that a bottom surface of the first opening is between a top surface of the supporting layer and a bottom surface of the supporting layer.
